(19) United States
(12) Patent Application Publication
(10) Pub. No.: US 2016/0359102 A1
(43) Pub. Date: Dec. 8, 2016

(54) MTJ STRUCTURE HAVING VERTICAL MAGNETIC ANISOTROPY

(71) Applicant: INDUSTRY-UNIVERSITY COOPERATION FOUNDATION HANYANG UNIVERSITY, Seoul (KR)

(72) Inventors: Jinpyo HONG, Seoul (KR); Jabin LEE, Seoul (KR)

(21) Appl. No.: 15/117,905

(22) PCT Filed: Jan. 29, 2015
(86) PCT No.: PCT/KR2015/001000

§ 371 Date: Aug. 10, 2016

(30) Foreign Application Priority Data
Feb. 11, 2014 (KR) 10-2014-0015384
Jan. 27, 2015 (KR) 10-2015-0012602

(51) Int. Cl. H01L 43/08; H01L 43/12; H01L 43/10

(52) U.S. Cl. CPC H01L 43/08; H01L 43/10; H01L 43/12; H01L 43/02

(57) ABSTRACT

Provided is a magnetic tunneling junction (MTJ) structure having (PMA). The MJT structure includes a seed layer including a tungsten-based substance, a first ferromagnetic layer that is positioned on the seed layer, includes a boron-based ferromagnetic material and has PMA, a tunneling barrier layer positioned on the first ferromagnetic layer, and a second ferromagnetic layer that is positioned on the tunneling barrier layer and has PMA, wherein the seed layer has a thickness in a range of 1 nm to 10 nm. Accordingly, by using the tungsten-based substance as a seed layer substance, the MTJ structure may be provided in which crystallinity of the first ferromagnetic layer is maintained even at a high temperature in a range of 350° C. to 400° C., a problem of the PMA reduction is prevented, and therefore, thermal stability is improved.

### TECHNICAL FIELD

The present invention relates to a magnetic tunneling junction (MTJ) structure having perpendicular magnetic anisotropy (PMA), and more particularly, to an MTJ structure having PMA that has thermal stability even at a high temperature.

### BACKGROUND ART

Next-generation nonvolatile memories that are attracting attention as new data storage media include ferroelectric random access memories (FeRAMs), magnetic random access memories (MRAMs), resistive random access memories (ReRAMs), phase-change random access memories (PRAMs), and the like. Each of these memories has its own advantages, and research and development are actively progressing according to the use.

Among these, an MRAM, which is a memory device using a quantum-mechanical effect called magnetoresistance (MR) and is a nonvolatile memory device with high density and response with lower power consumption, is a mass memory device which may replace dynamic random-access memories (DRAMs) which are currently widely used memory devices.

Two known magnetoresistance effects are giant magnetoresistance (GMR) and tunneling magnetoresistance (TMR).

A device using the GMR effect stores data using a phenomenon in which resistance of a conductor interposed between two ferromagnetic layers varies according to spin directions of the upper and lower ferromagnetic layers. However, since the GMR device has a low MR ratio, which is a ratio of change in MR, of 10%, a read signal of stored data is weak, and therefore the biggest challenge in implementing MRAMs is securing a read margin.

Meanwhile, a magnetic tunnel junction (MTJ) element using a change in MR according to the MTJ effect is the best known device using the TMR effect.

The MTJ device is formed with a stacked structure of a ferromagnetic layer/an insulating layer/a ferromagnetic layer. In the MTJ device, when spin directions of the upper and lower ferromagnetic layers are the same, the possibility of tunneling is maximized between the two ferromagnetic layers between which a tunnel insulating layer is interposed and the resistance accordingly becomes a minimum. On the other hand, when the spin directions are opposite each other, the possibility of tunneling is minimized and the resistance accordingly becomes a maximum.

In order to implement two spin states, a magnetization direction of any one ferromagnetic layer (a magnetic film) is fixedly set not to be influenced by external magnetization. Generally, a ferromagnetic layer in which a magnetization direction is fixed is referred to as a fixed layer or a pinned layer.

The magnetization direction of the other ferromagnetic layer (a magnetic film) is the same as or opposite that of the pinned layer. Here, the ferromagnetic layer is generally referred to as a free layer and serves to store data.

In the case of an MTJ device, an MR ratio, which is a ratio of change in resistance, greater than 50% is currently obtainable, and MTJ devices are becoming a leading force in the development of the MRAM.

Meanwhile, among MTJ devices, MTJ devices using a material having perpendicular magnetic anisotropy (PMA) are attracting attention.

Particularly, studies for applying an MTJ device using a material having PMA to a perpendicular spin transfer torque type magnetic random access memory (STT-MRAM) and the like are actively progressing.

A spin transfer torque (STT) type recording method is a method of inducing magnetization reversal by directly injecting a current into an MTJ instead of applying an external magnetic field. The STT recording method is advantageous for high density integration because no additional external wire is needed.

A material used for an MTJ using PMA may include CoFeB. Although CoFeB has been conventionally studied as a material having in-plane magnetic anisotropy, CoFeB was found to have PMA at a very low thickness (about 1.5 nm or less), and therefore has been actively studied.

As is already known, a junction having a structure of Ta/CoFeB/MgO is needed for CoFeB to exhibit PMA.

In the case of such a structure, B diffuses at a high temperature of 350° C. to 400° C., which is a heat treatment temperature during an actual process, and therefore there is a problem in that interface characteristics between a CoFeB layer and a Ta layer and PMA of the CoFeB layer may be degraded. That is, there is a problem in that the Ta/CoFeB/MgO structure is very thermally unstable.

### DISCLOSURE

### Technical Problem

The present invention is directed to providing a magnetic tunneling junction (MTJ) structure having perpendicular magnetic anisotropy (PMA) having thermal stability at a high temperature.

### Technical Solution

One aspect of the present invention provides a magnetic tunneling junction (MTJ) structure that includes a seed layer including a tungsten-based material, a first ferromagnetic layer that is positioned on the seed layer, includes a boron-based ferromagnetic substance, and has PMA, a tunneling barrier layer positioned on the first ferromagnetic layer, and a second ferromagnetic layer that is positioned on the tunneling barrier layer and has PMA, wherein the seed layer has a thickness in a range of 1 nm to 10 nm.

The tungsten-based material may include W or WB.

The boron-based ferromagnetic material may include CoFeB.

The tunneling barrier layer may include at least one selected from the group consisting of MgO, Al₂O₃, HfO₂, TiO₂, Y₂O₃, and Yb₂O₃.

The first ferromagnetic layer may maintain PMA after a heat treatment is performed at a temperature in a range of 350 ° C. to 400 ° C.

In addition, the tungsten-based material of the seed layer may have a beta phase or a mixed phase in which alpha and beta phases are mixed even after a heat treatment is performed at a temperature in a range of 350° C. to 400° C.

Another aspect of the present invention provides a magnetic device that includes a plurality of digit lines, a plurality bit lines crossing upper portions of the digit lines, and any one of the above-described MTJ structure interposed between the digit lines and the bit lines.

### Advantageous Effects

According to the present invention, by using a tungsten-based material as a seed layer material, the crystallinity of a first ferromagnetic layer is maintained at a high temperature in a range of 350° C. to 400° C., and the problem of perpendicular magnetic anisotropy (PMA) reduction is prevented.

Accordingly, a magnetic tunneling junction (MTJ) structure having PMA having improved thermal stability even at high temperature and a magnetic device including the same can be provided.

Effects of the present invention is not limited to the above-described effects, and other unmentioned effects may be clearly understood by those skilled in the art from the following descriptions.

### DESCRIPTION OF DRAWINGS

FIG. 1 is a cross-sectional view illustrating a magnetic tunneling junction (MTJ) structure having perpendicular magnetic anisotropy (PMA) according to one embodiment of the present invention.

FIG. 2 is a cross-sectional view illustrating an MTJ structure according to comparative example.

FIG. 3 is a cross-sectional view illustrating an MTJ structure according to manufacturing example.

FIG. 4 shows graphs of magnetic properties of an MTJ structure before and after a heat treatment according to comparative example. FIG. 5 shows graphs of magnetic properties of an MTJ structure before a heat treatment according to manufacturing example.

FIG. 6 shows graphs of magnetic properties of an MTJ structure after a heat treatment at a temperature of 350° C. according to manufacturing example.

FIG. 7 shows graphs of magnetic properties of an MTJ structures after a heat treatment at a temperature of 400° C. according to manufacturing example.

FIG. 8 shows X-ray diffraction (XRD) graphs of seed layers after heat treating the MTJ structures in which the seed layers are manufactured to have different thicknesses at a temperature of 350° C. according to manufacturing example.

### MODES OF THE INVENTION

Hereinafter, embodiments of the present invention will be described in detail with reference to the accompanying drawings as follows.

While the present invention allows various modifications and changes, the specific embodiments are exemplified with the accompanying drawings and will be described in detail below. However, the embodiments do not intend to limit the present invention by the specific forms described, and the present invention instead includes all of the modifications, equivalents, and alternatives in accordance with the scope defined by the appended claims.

When an element such as a layer, region or substrate is mentioned to be positioned “on” other elements, it may be understood that the element is directly positioned on the other elements or intermediate elements may also be interposed therebetween.

Although the terms such as a first, second, or the like may be used for describing various elements, compositions, regions, layers and/or areas, it may be understood that the various elements, compositions, regions, layers and/or areas are not limited to the terms.

In addition, the term used in the present invention “A/B/C multilayer structure” refers to a structure in which B and C layers are sequentially positioned on an A layer.

A magnetic tunneling junction (MTJ) structure having perpendicular magnetic anisotropy (PMA) according to one embodiment of the present invention will be described.

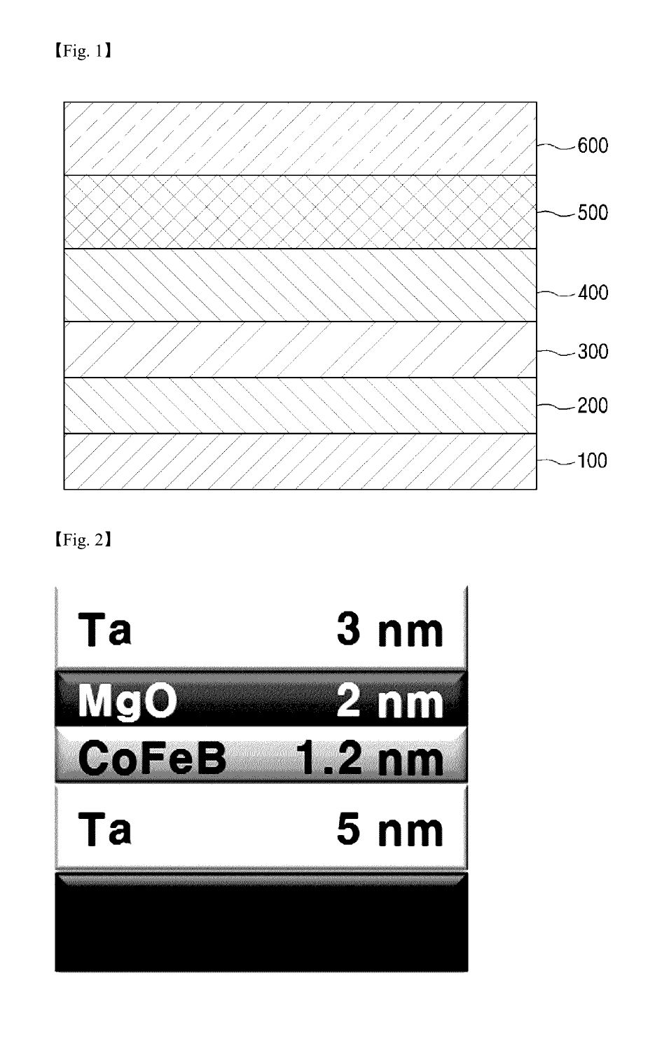

FIG. 1 is a cross-sectional view illustrating an MTJ structure having PMA according to one embodiment of the present invention.

Referring to FIG. 1, the MTJ structure includes a substrate 100, a seed layer 200, a first ferromagnetic layer 300, a tunneling barrier layer 400, a second ferromagnetic layer 500, and a capping layer 600. The substrate 100 may use a substrate formed of various known substances.

For example, the substrate 100 may be provided with a silicone substrate. Also, the substrate 100 may be provided as an electrode. Meanwhile, in some cases, the substrate 100 may be omitted.

The seed layer 200 is positioned on the substrate 100. The seed layer 200 may include a tungsten (W)-based material.

The W-based material has a better crystallinity than polycrystalline Ta which is almost amorphous and used as a conventional seed layer material and also has a low solid solubility for boron (B). Accordingly, the problem of crystallinity reduction due to material diffusion between the seed layer 200 and the first ferromagnetic layer 300 that will be described below may be minimized even at a high heat-treatment temperature.

Here, the seed layer 200 has a thickness in a range of 1 nm to 10 nm. When the thickness of the seed layer 200 is less than 1 nm, there is a problem in that magnetic properties are not revealed. This is because the crystal structure of a seed layer deposited too thin is not properly formed.

In addition, when the thickness of the seed layer 200 is greater than 10 nm, there is a problem in that PMA properties are not exhibited. This is because a seed layer having a preferred crystal orientation that is different from that of the ferromagnetic layer becomes excessively thick and thus a ferromagnetic layer may not have a naturally preferred crystal orientation.

Meanwhile, it is preferable that W used for the seed layer 200 be formed of beta-phase W or mixed-phase W in which alpha-phase and beta-phases are mixed.

W is classified into alpha-phase W and beta-phase W. Alpha-phase W is pure metallic W, has a body-centered cubic (bcc)(110) structure, and has a lattice constant (a) of 3.165 Å. In addition, beta-phase W is a type of A₃B such as W₃W, W₃O, and WO₃, has an A15 structure, and has a lattice constant (a) of 5.05 Å.

In general, it is known that a CoFeB magnetic layer needs an amorphous seed layer substance to have PMA. It is preferable that the CoFeB magnetic layer have a bcc(001) structure that is a naturally suitable crystal structure of CoFeB through a heat treatment after an amorphous CoFeB film is formed on the amorphous seed layer. When alpha-phase W is used for the seed layer, there is a possibility that a CoFeB layer formed on alpha-phase W does not have a bcc(001) crystal structure from the formation of the CoFeB layer as well as after a heat treatment but, instead, has a bcc(110) crystal structure along the crystal structure of alpha-phase W. On the other hand, when a CoFeB layer is formed on beta-phase W, there is a high possibility that the CoFeB layer is formed in an amorphous state due to a discontinuous crystal structure and, then, the CoFeB layer has a bcc(001) crystal structure through a following heat treatment. Accordingly, it is further preferable that beta-phase W rather than alpha-phase W be used for the seed layer 200 due to the above-described reason.

In addition, according to the present invention, a W-based substance of the seed layer 200 has a beta phase or a mixed phase in which alpha and beta phases are mixed after a heat treatment is performed at a temperature in a range of 350° C. to 400° C.

This is because that when the thickness of the seed layer 200 is 10 nm or less, a phase transition to an alpha phase like experimental example 3 that will be described below does not occur.

When, the thickness of the seed layer is greater than 10 nm, the W-based material of the seed layer 200 has an alpha phase at a heat treatment temperature in a range of 350° C. to 400° C. For example, when W having a beta phase or a mixed phase in which alpha and beta phases is mixed is used for the seed layer 200 in a thin film state, and the thickness of the seed layer 200 is greater than a critical thickness of 10 nm, beta-phase W is phase-transitioned to alpha-phase W while a heat treatment is performed at a temperature of about 200° C.

Accordingly, when a heat treatment is performed at a temperature in a range of 350° C. to 400° C. which is a heat treatment temperature during an actual process and the thickness of the W-based seed layer 200 is 10 nm or less, a phase transition to an alpha phase does not occur, and a beta phase or a mixed phase in which alpha and beta phases are mixed is maintained instead and PMA properties are exhibited. However, when the thickness of the W-based seed layer 200 is greater than 10 nm, a phase transition to an alpha phase occurs, and PMA properties are not exhibited.

The seed layer 200 may be formed using a general deposition method. For example, the seed layer 200 may be formed using a physical vapor deposition method, a chemical vapor deposition method, a sputtering method, or a solution-processing method.

The first ferromagnetic layer 300 is positioned on the seed later 200. The ferromagnetic layer 300 includes a B-based ferromagnetic material and has PMA. For example, the B-based ferromagnetic material may include CoFeB.

The first ferromagnetic layer 300 including CoFeB may be formed to have a thickness of 1.5 nm or less to have PMA.

The first ferromagnetic layer 300 may be formed using a general deposition method. For example, the first ferromagnetic layer 300 may be formed using a physical vapor deposition method, a chemical vapor deposition method, a sputtering method, or a solution-processing method.

Meanwhile, although PMA of the first ferromagnetic layer 300 may already be revealed during formation of the first ferromagnetic layer 300, the first ferromagnetic layer 300 may also have PMA through a technique including a heat treatment, and the like after the first ferromagnetic layer 300 is formed.

The first ferromagnetic layer 300 may be a pinned or free layer.

The magnetization direction of the pinned layer is fixedly set not to be influenced by external magnetization.

The magnetization direction of the free layer may be the same as or opposite to that of the pinned layer according to a magnetization direction of an applied magnetic field and thus serve to store data.

The tunneling barrier layer 400 is positioned on the first ferromagnetic layer 300. That is, the tunneling barrier layer 400 is interposed between the first ferromagnetic layer 300 and the second ferromagnetic layer 500 that will be described below.

Accordingly, the material of the tunneling barrier layer 400 may be any material as long as the material is an insulating substance.

For example, the insulating material may be at least one selected from the group consisting of MgO, Al₂O₃, HfO₂, TiO₂, Y₂O₃, and Yb₂O₃. The tunneling barrier layer 400 may preferably be an MgO layer.

The tunneling barrier layer 400 may be formed using a general deposition method. For example, the tunneling barrier layer 400 may be formed using a physical vapor deposition method, a chemical vapor deposition method, a sputtering, method or a solution-processing method.

The second ferromagnetic layer 500 is positioned on the tunneling barrier layer 400. When the first ferromagnetic layer 300 is a pinned layer, the second ferromagnetic layer 500 may be a free layer, and when the first ferromagnetic layer 300 is a free layer, the second ferromagnetic layer 500 may be a pinned layer.

Here, the second ferromagnetic layer 500 includes a ferromagnetic material having PMA as a main element. Accordingly, the second ferromagnetic layer 500 may include at least one selected from the group consisting of Fe, Co, Ni, B, Si, Zr, Pt, Tb, Pd, Cu, W, Ta, and a compound thereof to have PMA.

For example, the second ferromagnetic layer 500 may include CoFeB. Here, a CoFeB layer may be set to be thin to have PMA. For example, the CoFeB layer may be set to 1.5 nm or less to have PMA.

The second ferromagnetic layer 500 may be formed using a general deposition method. For example, the second ferromagnetic layer 500 may be formed using a physical vapor deposition method, a chemical vapor deposition method, a sputtering method, or a solution-processing method.

Meanwhile, although PMA of the second ferromagnetic layer 500 may be already formed during formation of the second ferromagnetic layer 500, the second ferromagnetic layer 500 may also have PMA through a technique including a heat treatment, and the like after the second ferromagnetic layer 500 is formed.

The capping layer 600 is positioned on the second ferromagnetic layer 500. The capping layer 600 serves as a protection layer and protects the second ferromagnetic layer 500 from being oxidized. The capping layer 600 may be omitted in some cases.

Hereinafter, a magnetic device including the MTJ structure having PMA according to one embodiment of the present invention will be described. The magnetic device may include a plurality of digit lines, a plurality of bit lines crossing upper portions of the digit lines, and MTJs interposed between the digit lines and the bit lines.

Here, the MTJ includes a seed layer including a W-based substance, a first ferromagnetic layer that is positioned on the seed layer, includes a B-based ferromagnetic substance, and has PMA, a tunneling barrier layer positioned on the first ferromagnetic layer, and a second ferromagnetic layer that is positioned on the tunneling barrier layer and has PMA. Here, the thickness of the seed layer is in a range of 1 nm to 10 nm.

Such an MTJ is the MTJ described above with reference to FIG. 1, and the specific description thereof will be omitted.

According to the present invention, by using the W-based substance for the seed layer of an MTJ structure, crystallinity of the first ferromagnetic layer is maintained even at a high temperature in a range of 350° C. to 400° C., and a problem of PMA reduction may be prevented.

Accordingly, the magnetic device including the MTJ structure having PMA having improved thermal stability even at a high temperature may be provided.

### Comparative Example

A structure of a Ta seed layer/a first ferromagnetic layer/a tunneling barrier layer/a capping layer was manufactured as an MTJ structure that has PMA using a Ta-based substance for a seed layer. Here, for the sake of experimental convenience, a process including forming the second ferromagnetic layer on the tunneling barrier layer was omitted when the MTJ structure was manufactured.

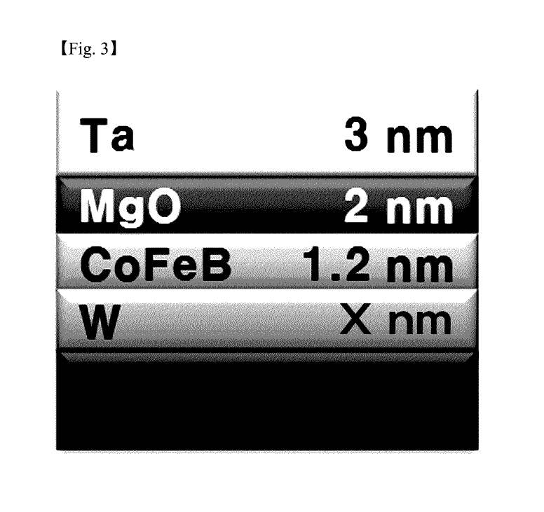

FIG. 2 is a cross-sectional view illustrating an MTJ structure according to Comparative example.

Referring to FIG. 2, an MTJ structure in which a Ta seed layer having a thickness of 5 nm, a CoFeB layer having a thickness of 1.2 nm, a MgO layer having a thickness of 2 nm, and a Ta capping layer having a thickness of 3 nm were sequentially stacked on a substrate was manufactured.

### Manufacturing Example

A structure of a W seed layer/a first ferromagnetic layer/a tunneling barrier layer/a capping layer was manufactured as an MTJ structure that has PMA using a W-based substance for a seed layer. Here, for the sake of experimental convenience, a step of forming the second ferromagnetic layer on the tunneling barrier layer was omitted when the MTJ structure was manufactured.

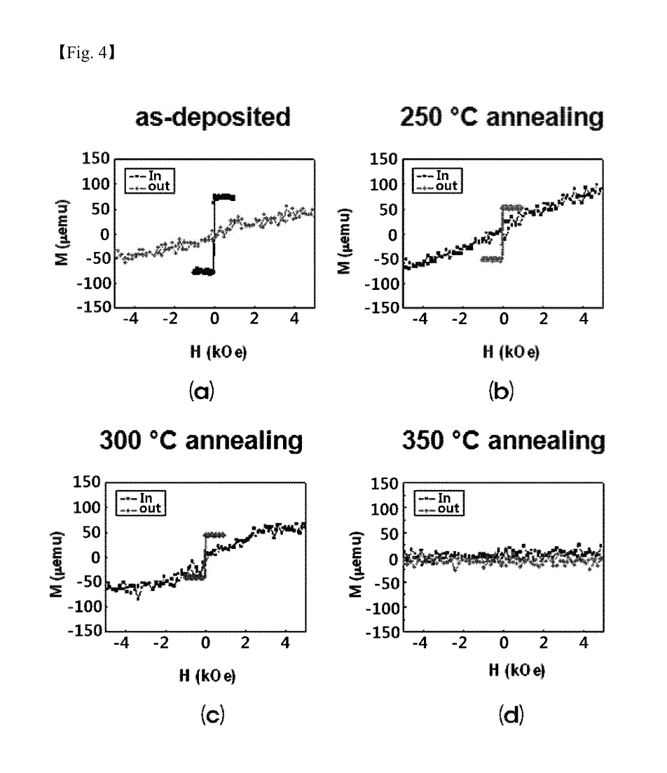

FIG. 3 is a cross-sectional view illustrating an MTJ structure according Manufacturing example.

Referring to FIG. 3, MTJ structures were manufactured in which W seed layers having various thicknesses of X nm, CoFeB layers having a thickness of 1.2 nm, MgO layers having a thickness of 2 nm, and Ta capping layer having a thickness of 3 nm were respectively sequentially stacked on substrates.

Here, the W seed layers were set to have thicknesses (t_{w}) of 1.9 nm, 3.7 nm, 5.6 nm, 10.0 nm, and 18.0 nm to manufacture the MTJ structures.

### Experimental Example 1

Magnetic properties of the MTJ structure according to comparative example were analyzed before and after heat treatments.

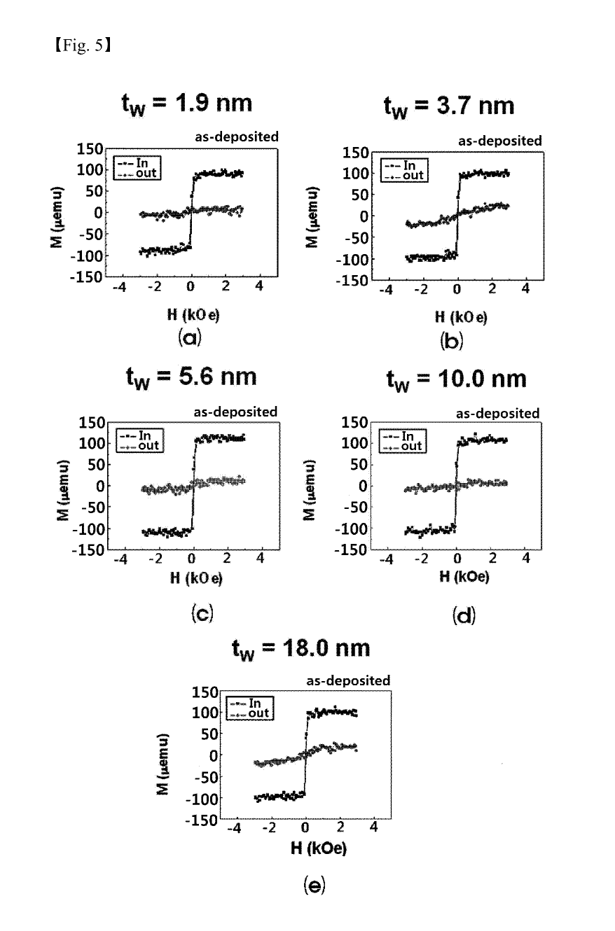

FIG. 4 shows graphs of magnetic properties of an MTJ structure before and after heat treatments according comparative example.

Referring to FIG. 4, it is apparent that when no heat treatment was performed (as-deposited), the MTJ structure shows properties of in-plane magnetic anisotropy, and when heat treatments were performed at temperatures of 250° C. and 300° C., the MTJ structure shows PMA.

However, it is apparent that when a heat treatment was performed at a temperature of 350° C., PMA tends to be disappeared.

### Experimental Example 2

Magnetic properties of MTJstructures according to manufacturing example were analyzed before and after heat treatments were performed at temperatures of 350° C. and 400° C.

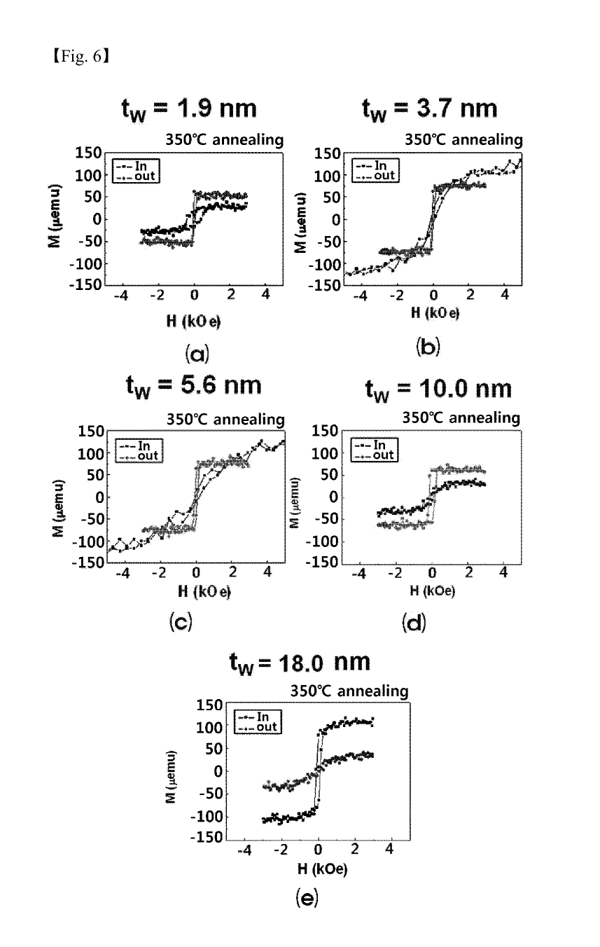

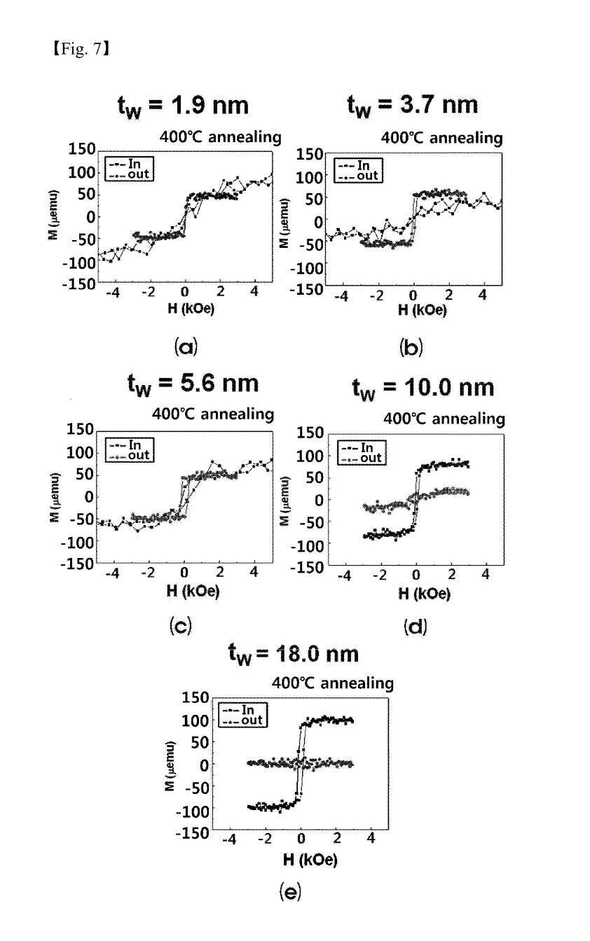

FIG. 5 shows graphs of magnetic properties of an MTJ structures before a heat treatment according to the manufacturing example, FIG. 6 shows graphs of magnetic properties of MTJ structures after a heat treatment at a temperature of 350° C. according to the Manufacturing example, and FIG. 7 shows graphs of magnetic properties of MTJ structures after a heat treatment at a temperature of 400° C. according to the manufacturing example.

Referring to FIG. 5, it is apparent that in the cases of the W seed layers having thicknesses of 1.9 nm, 3.7 nm, 5.6 nm, 10 nm, and 18 nm before a heat treatment, all of the MTJ structures show properties of in-plane magnetic anisotropy.

Referring to FIGS. 6 and FIGS. 7, it is apparent that in the cases of performing heat treatments at temperatures of 350° C. and 400° C. and the W seed layers having thicknesses of 1.9 nm, 3.7 nm, and 5.6 nm, the MTJ structures show PMA.

Meanwhile, in case that the W seed layer has a thickness of 10.0 nm, it is apparent that the MTJ structure shows PMA when a heat treatment was performed at a temperature of 350° C., and PMA of the MTJ structure shows starts to be disappeared when a heat treatment was performed at a temperature of 400° C.

In addition, it is apparent that in the cases in which the W seed layer had a thickness of 18.0 nm and heat treatments were performed at temperatures of 350 and 400° C., PMA properties of the MTJ structure start to be disappeared and properties of in-plane magnetic anisotropy are revealed.

### Experimental Example 3

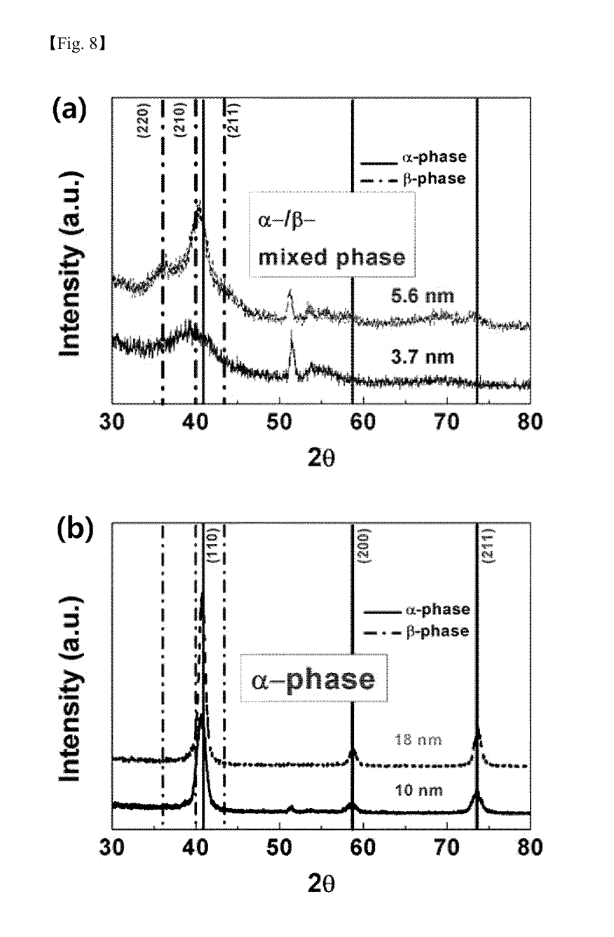

FIG. 8 shows X-ray diffraction (XRD) graphs of seed layers after heat treating MTJ structures in which the seed layers are manufactured to have different thicknesses at a temperature of 350° C. according manufacturing example.

FIG. 8A is an XRD graph of seed layers having thicknesses of 3.7 nm, and 5.6 nm, and FIG. 8B is an XRD graph of seed layers having thicknesses of 10 nm and 18 nm.

Referring to FIG. 8A, in the cases in which the samples have seed layers having thicknesses of less than 10 nm and having PMA properties even after a heat treatment was performed at a temperature of 350° C., XRD peaks of mixed phases in which alpha and beta phases are mixed are shown.

Alternatively, referring to FIG. 8B, in the case in which the sample has a seed layer having a thickness of 18 nm and having PMA properties that disappeared after a heat treatment was performed at a temperature of 350° C., a clear XRD peak of an alpha phase is shown.

According to the present invention, by using the W-based substance as the seed layer substance, crystallinity of the first ferromagnetic layer may be maintained even at a high temperature in a range of 350° C. to 400° C., and a problem of PMA reduction may be prevented.

Accordingly, the MTJ structure having PMA having improved thermal stability even at a high temperature and the magnetic device including the same may be provided.

The embodiments disclosed in the drawings and specification are only for describing specific examples to help understanding and are not for limiting the concept of the present invention. It is clear to those in the art that modified embodiments in addition to the embodiments disclosed in the present specification may be made on the basis of the technical concept of the present invention.

1. A magnetic tunneling junction (MTJ) structure having perpendicular magnetic anisotropy (PMA), comprising:
a seed layer including a tungsten-based material;
a first ferromagnetic layer that is positioned on the seed layer, includes a boron-based ferromagnetic material, and has PMA;
a tunneling barrier layer positioned on the first ferromagnetic layer; and
a second ferromagnetic layer that is positioned on the tunneling barrier layer and has PMA, wherein the seed layer has a thickness in a range of 1 nm to 10 nm.

2. The MTJ structure of claim 1, wherein the tungsten-based material includes W or WB.

3. The MTJ structure of claim 1, wherein the boron-based ferromagnetic material includes CoFeB.

4. The MTJ structure of claim 1, wherein the tunneling barrier layer includes at least one selected from the group consisting of MgO, Al₂O₃, HfO₂, TiO₂, Y₂O₃, and Yb₂O₃.

5. The MTJ structure of claim 1, wherein the first ferromagnetic layer maintains PMA even after a heat treatment is performed at a temperature in a range of 350° C. to 400° C.

6. The MTJ structure of claim 1, wherein the tungsten-based substance of the seed layer has a beta phase or a mixed phase in which alpha and beta phases are mixed after a heat treatment is performed at a temperature in a range of 350° C. to 400° C.

7. A magnetic device comprising:
a plurality of digit lines;
a plurality bit lines crossing upper portions of the digit lines; and
the magnetic tunneling junction (MTJ) structure of any one of claims 1 to 6 that is interposed between the digit lines and the bit lines.
